(19) United States
(12) Patent Application Publication
(10) Pub. No.: US 2012/0156424 A1
(43) Pub. Date: Jun. 21, 2012

(54) GRAPHENE-SILICON CARBIDE-GRAPHENE NANOSHEETS

(75) Inventors: Kuei-hsien Chen, Taipei (TW); Ming-Shien Hu, Taipei City (TW); Chun-Chiang Kuo, Changhua County (TW); Li-chyong Chen, Taipei (TW)

(73) Assignee: Academia Sinica, Taipei (TW)

(21) Appl. No.: 12/968,913

(22) Filed: Dec. 15, 2010

(51) Int. Cl. B32B 5/00; C23C 16/32; H05H 1/46; B32B 9/04; C23C 16/26; B82Y 30/00

(52) U.S. Cl. 428/119; 428/446; 428/337; 427/249.6; 427/575; 427/577; 977/773

(57) ABSTRACT

A nanosheet includes a 2H—SiC layer having a first surface and a second surface, the first and second surfaces being opposed to each other; a first graphene layer formed of 1-10 graphenes being disposed on the first surface; and a second graphene layer formed of 1-10 graphenes being disposed on the second surface.

### BACKGROUND

Although diamond and graphite are the most widely recognized crystal structures of carbon, other structures, including carbon nanotubes and graphene, possess promising electronic and other technologically relevant properties. Graphene, which is composed of a single layer or a small number of layers of graphite, has unique properties due to its essentially two-dimensional nature. The use of graphene has been proposed in a wide range of applications, such as electronics, sensors, hybrid composites, and energy storage and conversion devices.

Several synthetic routes, such as mechanical exfoliation, chemical oxidation, and epitaxial growth, can be used for the synthesis of graphene. In mechanical exfoliation, an adhesive tape is used to separate single (or a small number of) graphene layers from a thick graphene sample. The resulting free-standing graphene can be placed onto a substrate, such as an oxidized silicon wafer. Chemical oxidation produces large quantities of graphene oxide layers in an aqueous solution; the graphene oxide layers can then be reduced into graphene upon the introduction of an appropriate reduction agent. Epitaxial growth methods can be used to grow graphene layers directly onto a substrate, such as transition metal or 4H- or 6H-silicon carbide substrates.

### SUMMARY

In a general aspect, a nanosheet includes a 2H—SiC layer having a first surface and a second surface, the first and second surfaces being opposed to each other; a first graphene layer formed of 1-10 graphenes being disposed on the first surface; and a second graphene layer formed of 1-10 graphenes being disposed on the second surface.

Embodiments may include one or more of the following.

The 2H—SiC layer has a thickness of 3-15 nm, or 3-7 nm.

At least one of the first surface and the second surface is a 2H—SiC {001} crystal plane.

The nanosheet is disposed on a surface of a substrate, the first and second surfaces of the 2H—SiC layer being substantially perpendicular to the substrate surface. The substrate is silicon; germanium; a ceramic material; a carbonaceous material; a metal selected from the group consisting of Ni, Co, Fe, W, Mo, and stainless steel; or a combination thereof. The substrate is silicon or germanium and the surface of the substrate is a {100}, {110}, or {111} crystal plane.

The nanosheet further includes a plurality of nanoparticles disposed on the first or second graphene layer. The plurality of nanoparticles each is formed of a metal, a metal oxide, a metal nitride, or combination thereof.

The nanosheet further includes a plurality of ions intercalated in the first or second graphene layer, the ions being selected from the group consisting of Li, Na, Be, Mg, and Ca.

At least one of the first graphene layer and the second graphene layer is tensilely strained or compressively strained.

In another general aspect, an article includes a substrate having a surface; and a plurality of nanosheets disposed on the surface of the substrate. Each nanosheet includes a SiC layer having a first surface and a second surface, the first and second surfaces opposed to each other and substantially perpendicular to the surface of the substrate, a first graphene layer formed of 1-10 graphenes being disposed on the first surface, and a second graphene layer formed of 1-10 graphenes being disposed on the second surface. The density of nanosheets per unit area is at least 10⁹ cm⁻².

Embodiments may include one or more of the following.

The density of nanosheets per unit area is in the range of 10⁹ to 10¹² cm⁻².

The SiC layer is formed of 2H—SiC.

In another aspect, a method of making an article includes placing a substrate in a chemical vapor deposition reactor that contains a gas mixture; and heating the substrate at a temperature in the range of about 900-1250° C. such that a plurality of nanosheets are formed on a surface of the substrate. The gas mixture comprises an inert gas, a silicon-containing gas, a carbon-containing gas, and hydrogen gas. The article includes a substrate having a surface; and a plurality of nanosheets disposed on the surface of the substrate. Each nanosheet includes a SiC layer having a first surface and a second surface, the first and second surfaces opposed to each other and substantially perpendicular to the surface of the substrate, a first graphene layer formed of 1-10 graphenes being disposed on the first surface, and a second graphene layer formed of 1-10 graphenes being disposed on the second surface. The density of nanosheets per unit area is at least 10⁹ cm⁻².

Embodiments may include one or more of the following.

The silicon-containing gas is silane. The carbon-containing gas is methane.

A pressure in the chemical vapor reactor is in the range of 40-80 Torr.

The chemical vapor deposition reactor is at least one of a microwave plasma reactor, a radio frequency plasma reactor, an induction coupled plasma reactor, a direct current plasma reactor, or a hot filament reactor.

The graphene-silicon carbide (SiC)-graphene (GSG) nanosheets described herein have a number of advantages.

Large-area growth of GSG nanosheets can be achieved via a simple and inexpensive process that is compatible with existing semiconductor (e.g., Si-based) manufacturing processes. The use of a bottom-up fabrication process offers precise control of the dimensions of the GSG nanosheets as well as their number density on a substrate. For instance, ultrathin nanosheets having a thickness that is less than the resolution limit of conventional top-down lithographic processes (e.g., less than about 10 nm thick) can be readily grown via bottom-up fabrication. High number densities (e.g., 10⁹-10¹² cm⁻²) can be achieved.

2H type silicon carbide (2H—SiC) wafers are not commercially available and thus top-down fabrication processes cannot be used to create structures using 2H—SiC. In a bottom-up fabrication process, however, GSG nanosheets including 2H—SiC layers can be grown directly by appropriate control of the growth conditions.

The large available surface area in a sample of GSG nanosheets provides good electronic and electrochemical properties that are desirable in a wide range of applications, such as electronic devices, superconductors, capacitors, fuel cells, electrochemistry, sensing, field emission, hydrogen storage, and other energy-related technologies. For instance, the residual tensile or compressive strain, high surface-to-volume ratio, high electrical conductivity, high number density, and sharp edges of vertically oriented graphene layers of GSG nanosheets makes the nanosheets advantageous as nano-structured electrode materials for advanced electrochemical energy devices and ultrasensitive chemical and biological sensors. Furthermore, the availability of the highly chemically active edge plane in addition to the less active basal plane makes GSG nanosheets well-suited to use in catalysis and electrochemical energy conversion and storage applications.

Other features and advantages of the invention are apparent from the following description and from the claims.

### BRIEF DESCRIPTION OF DRAWINGS

FIG. 1A is a schematic diagram of a graphene-silicon carbide (SiC)-graphene (GSG) nanosheet.

FIGS. 1B and 1C are scanning electron microscopy (SEM) images of GSG nanosheets viewed from a tilted angle and via cross section, respectively.

FIG. 2A is a transmission electron microscopy (TEM) image of a GSG nanosheet.

FIG. 2B is a diffraction pattern of the nanosheet shown in FIG. 3A, obtained via TEM.

FIGS. 3A-3C are SEM micrographs of GSG nanosheets having two, three, and four graphene layers, respectively.

FIGS. 4A-4C are schematic diagrams of the growth mechanism for GSG nanosheets.

FIGS. 5A and 5B are Raman spectra of the G band and the 2D band, respectively, of the graphene layers of a GSG nanosheet.

FIG. 6A is a cyclic voltammograph of a GSG nanosheet electrode.

FIG. 6B is a plot of current density versus the square root of the scan rate for a cyclic voltammetry scan of a nanosheet electrode.

FIG. 7A is a schematic diagram of nanoparticles deposited onto a GSG nanosheet.

FIG. 7B is a TEM image of Pt nanoparticles deposited onto a nanosheet.

FIG. 7C is a histogram of the size distribution of the nanoparticles shown in FIG. 7A.

FIG. 8A is a cyclic voltammograph for the oxidation of methanol using various electrodes.

FIG. 8B is a plot of the stability of the mass activity of various electrodes during the oxidation of methanol.

### DETAILED DESCRIPTION

### 1 Structure and Fabrication

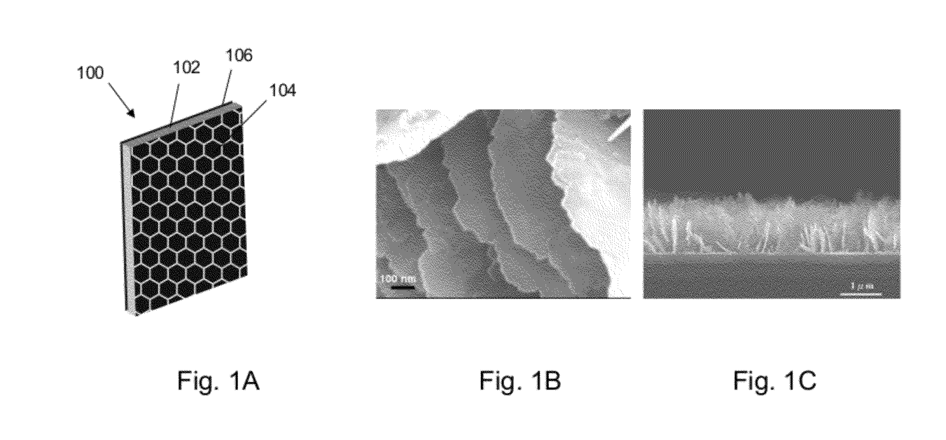

Referring to FIG. 1A, a graphene-silicon carbide (SiC)-graphene (GSG) nanosheet 100 is formed of a central SiC layer 102 sandwiched by graphene layers 104, 106. Referring to FIGS. 1B and 1C, scanning electron microscopy (SEM) images show nanosheets from a tilted angle and in cross-section, respectively.

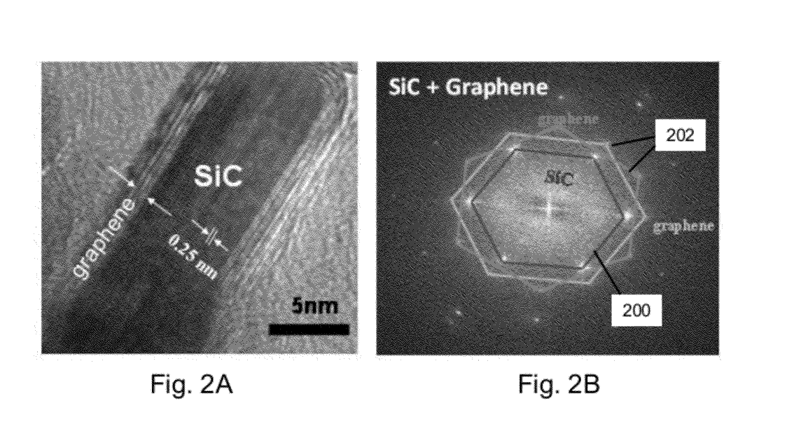

SiC layer 102 is less than 100 nm in thickness (e.g., less than 50 nm thick, 3-50 nm thick, 3-15 nm thick, or 3-7 nm thick). SiC layer 102 has a 2H crystal structure, with graphene layers 104 and 106 formed on an {001} crystal planes of the SiC layer. Referring to FIG. 2A, a transmission electron microscopy (TEM) image of a GSG 100 shows graphene layers 104, 106 surrounding an SiC layer 102 of approximately 5-7 nm thickness. The spacing between planes in the SiC crystal is measured to be 0.25 nm. Referring also to FIG. 2B, a diffraction pattern of the nanosheet shown in FIG. 2A confirms the presence of both graphene (via a graphene diffraction pattern 200) and SiC (via an SiC diffraction pattern 202).

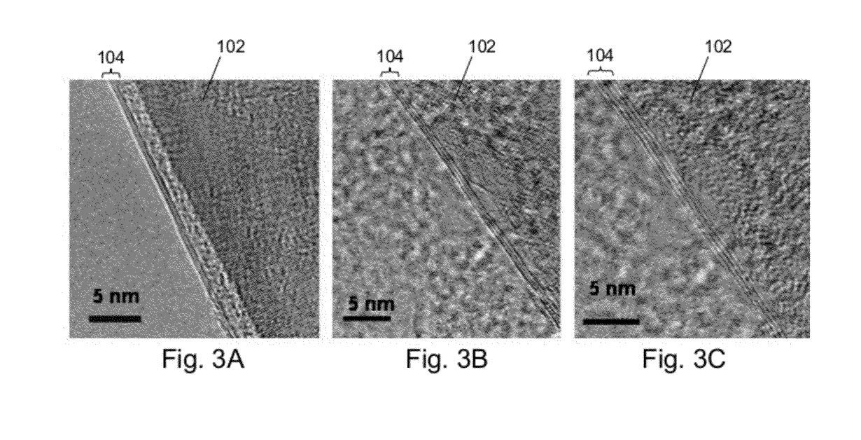

The number of single graphene sheets included in graphene layers 104, 106 on a GSG nanosheet 100 can be controlled via growth parameters, as described in greater detail below. For instance, one or both of graphene layers 104, 106 may be composed of 1-10 single sheets of graphene. Referring to FIGS. 3A-3C, SEM images show GSG nanosheets having graphene layers composed of two, three, and four single graphene sheets, respectively.

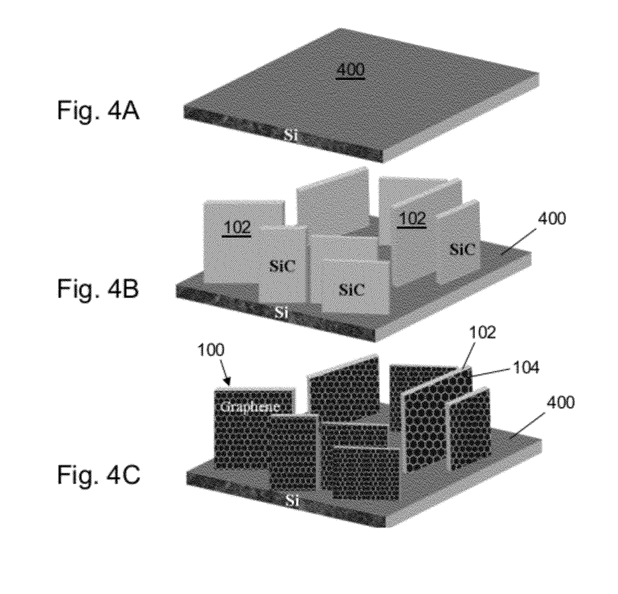

Referring to FIGS. 4A-4C, GSG nanosheets 100 are grown on a substrate 400. Substrate 400 may be composed of one or more materials including, for instance, silicon, germanium, a carbonaceous material (e.g., carbon fiber, carbon cloth, glassy carbon, carbon paper, or highly ordered pyrolytic graphite (HOPG)), or a metal such as Ni, Co, Fe, W, Mo, or stainless steel. In other cases, the substrate may be formed of a porous material, a ceramic material (e.g., indium tin oxide (ITO)), or a composite material. In the case of silicon, nanosheets 100 may be grown on {111}, {110}, or {100} type surfaces. The nanosheets 100 are oriented such that the boundaries between SiC layer 102 and graphene layers 104, 106 are substantially perpendicular to a top surface of the substrate.

GSG nanosheets are directly grown via a bottom-up approach using chemical vapor deposition (CVD) techniques, such as a microwave plasma, radio frequency (RF) plasma, induction coupled plasma, direct current (DC) plasma, or hot filament CVD approach. In the case of a Si substrate, a bare Si substrate is placed into a CVD chamber and cleaned using a microwave hydrogen plasma for a few minutes to remove the native oxide from the top surface of the substrate. A gas mixture hydrogen, methane, and silane is then introduced into the CVD chamber to grow 2H—SiC layers 102. In some cases, the gas mixture may include a silicon-containing gas other than silane or a carbon-containing gas other than methane, and may also include an inert gas and/or a halogen-containing gas. The growth step proceeds for a few hours with a microwave power in the range of 1000-2200 W, a CVD chamber pressure of 40-80 Torr, and a temperature in the range of 500-1500° C., preferably, 900-1250° C. (e.g., 1200° C.). In the growth process of SiC, growth temperature is one of the most critical process parameters for controlling the phase. Surface graphitization of the 2H—SiC layers 102 is performed in a single step chemical reaction in a microwave plasma environment for a few minutes, leaving excess carbon atoms on the surface of the 2H—SiC layers in the form of graphene sheets.

GSG nanosheets can be grown in a variety of sizes, such as 1 μm×1 μm, 5 μm×5 μm, or 10 μm×10 μm. The size of the nanosheets is controllable via the growth parameters. In addition, the number density and growth orientation of the nanosheets can be varied by controlling growth conditions such as the gas composition, reaction temperature, chamber pressure, and microwave power. Due to lattice mismatch between SiC layer 102 and graphene layers 104, 106, residual strain develops in the graphene layers of GSG nanosheets 100. The residual strain can also be controlled by altering the gas flow ratio of hydrogen to methane (H₂/CH₄). For example, a higher gas flow ratio of H₂/CH₄ gives compressive strain while a lower flow ratio results in tensile strain. Alternatively, the strain can be relaxed by controlling the layer number (n) of graphene. For example, residual strain in few-layer (n=1˜4) graphene is higher than that in muti-layer graphene (n>15).

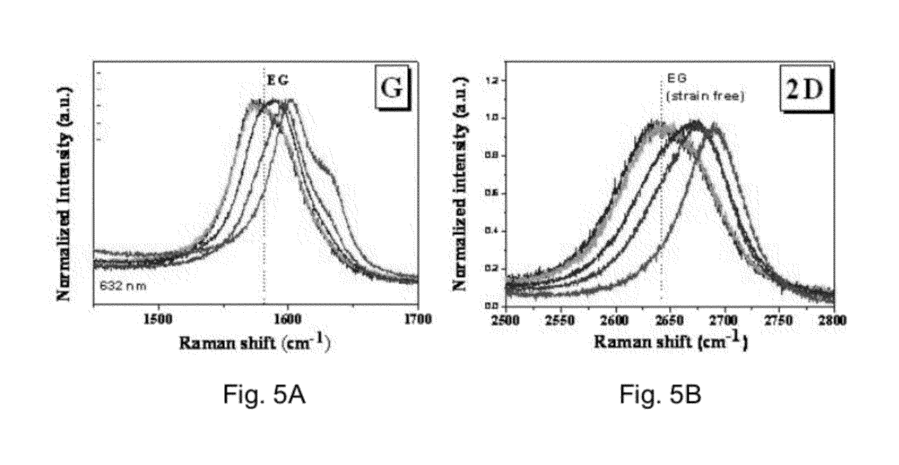

Referring to FIGS. 5A and 5B, the strain in the graphene layers can be monitored by shifts in the G band (FIG. 5A) and 2D band (FIG. 5B) of the Raman spectra of the graphene. In FIGS. 5A and 5B, each Raman spectrum was obtained from a sample grown with a given gas flow ratio of H₂/CH₄. From left to right in FIGS. 5A and 5B, each curve represents the result obtained from a gas flow ratio (H₂/CH₄) of 3, 5, 10, 20, or 40. These results demonstrate that the residual strain in the graphene layers is controllable by varying the growth conditions. The residual strain in the graphene layers may be either tensile or compressive.

### 2 Applications

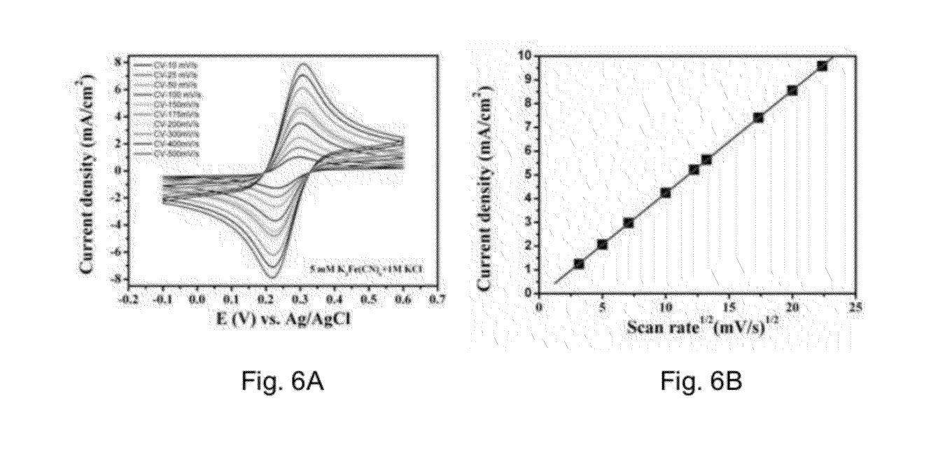

Referring to FIGS. 6A and 6B, GSG nanosheets are suitable for use as electrodes in electrochemistry applications. In one example, a substrate containing GSG nanosheets is established as the working electrode in an electrochemical system having 5 mM K₃FE(CN)₆⁺¹ M KCl as the electrolyte, 3 M Ag/AgCl as the reference electrode, and Pt as the counter electrode. Cyclic voltammograph (CV) scans (FIG. 6A) show an oxidation-reduction peak difference of 61 mV, which is quite close to 58 mV, the value for an ideal two-electron transfer system. A plot of current density versus the square root of the scan rate (FIG. 6B) shows a linear relation, indicating diffusion control of the system.

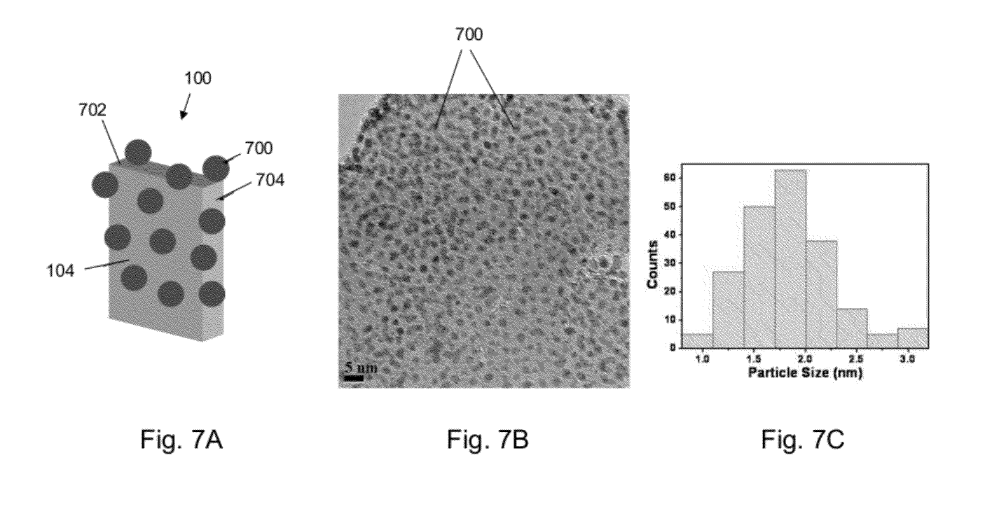

Referring to FIG. 7A, nanoparticles 700 can be grown on GSG nanosheets 100 via deposition techniques such as ion-beam sputtering, magnetron sputtering, or electron beam sputtering. Alternatively, nanoparticles can be grown on GSG nanosheets via chemical methods, such as an ethylene glycol reduction method. Nanoparticles are deposited not only on the outer surfaces of graphene layers 104, 106, but also on top 702 and side 704 edges of the nanosheet. The nanoparticles may be formed of a metal (e.g., transition metals such as Pt or Ru), a metal oxide, a metal nitride, or a combination thereof. Referring to FIGS. 7B and 7C, analysis of TEM images of well-dispersed Pt nanoparticles on a GSG nanosheet reveals an average size of about 1.7 nm, which is appropriate for catalytic applications such as fuel cell electrodes.

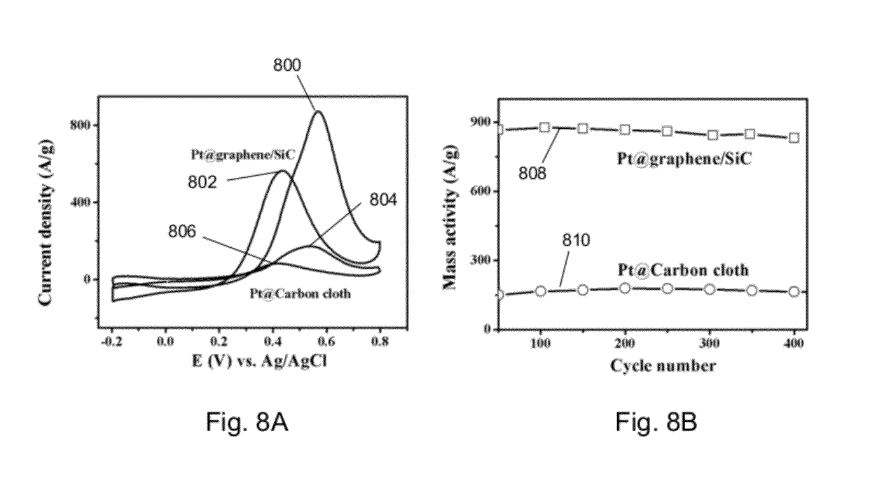

In an example, to demonstrate the catalytic activity of GSG nanosheets with Pt nanoparticles (Pt@GSG), the oxidation of 0.5 M methanol in 0.1 M HClO₄ electrolye using various electrodes composed of Pt nanoparticles and some form of carbon was measured. Referring to FIG. 8A, peaks 800, 802 correspond to oxidation via Pt@GSG electrodes; peaks 804 and 806 correspond to oxidation via Pt@carbon cloth electrodes. Pt@carbon cloth, as well as other types of electrodes such as Pt@carbon black and Pt@carbon nanotubes, suffer from CO poisoning that reduces the strength of the oxidation peak. In contrast, peaks 800, 802 reflect the strong oxidation enhancement enabled by Pt@GSG electrodes.

Referring to FIG. 8B, a significant enhancement of the mass activity was observed for Pt@GSG electrodes (curve 808) as compared to Pt@carbon cloth electrodes (curve 810), which may be due to (1) the electronic interplay between Pt nanoparticles and the strained graphene layers and (2) the strain effect of graphene on the lattice of Pt nanoparticles.

In general, the enhancement of chemical reactions can be achieved by depositing or growing any catalyst nanoparticles onto GSG nanosheets (catalyst nanoparticle@GSG structures). Enhanced hydrogen storage was also observed for catalyst nanoparticle@GSG structures as compared to Pt@carbon cloth structures. Given that the residual strain in the graphene layers of GSG nanosheets can be tailored via the growth conditions, the enhancement potential (e.g., for chemical reactions or hydrogen storage) of nanoparticle@GSG structures can be controlled during the fabrication process.

In general, for catalysis applications such as fuel cells, catalytic (i.e., chemical activity) enhancement of metal catalysts is important for cost-effective, high-performance fuel cell devices. The size, composition, and shape of the catalysts as well as the structure and surface chemistry of the catalyst support play a critical role in catalytic enhancement. For instance, the structure of the catalyst support influences the interaction between catalyst and support as well as the properties of the catalyst itself (e.g., size, shape, and strain of deposited catalyst nanoparticles). The presence and controllability of residual strain in the graphene layers of GSG nanosheets enables the manipulation of strain in deposited catalyst nanoparticles in a controllable way, allowing exploration of fundamental properties of catalysis.

In another application, a composite electrode that acts as a supercapacitor can be formed from GSG nanosheets and reduction/oxidation (redox) materials, such as oxides, nitrides, organic materials, or polymeric materials.

In some cases, atoms or ions may be intercalated into one or both graphene layers of a GSG nanosheet. With certain intercalated ions, such as alkali metals (e.g., Li or Na), GSG nanosheets can be used as battery electrodes. With certain intercalated ions, such as alkaline metals (e.g., Be, Mg, or Ca), GSG nanosheets can be used as superconducting materials. With certain intercalated atoms, such as Au and Br (See Physical Review B, 2010, 88, 235408; and ACS Nano, Article ASAP DOI: 10.1021/nn102227u), GSG nanosheets can be used as optoelectronic materials, electromagnetic materials, or magnetooptical materials. Other intercalants, such as diatomic molecules (e.g., halogens such as metal chlorides or metal bromides, metal oxides, or metal sulfides) or large organic molecules may also be useful as intercalant materials in GSG nanosheets.

Intercalation of metallic ions into the graphitic interlayer of graphene is performed by a two-zone vapor transport method. The intercalant ions are heated to a first temperature T1 and the host material (graphene), which is positioned some distance away from the intercalants, is heated to a second temperature T2, where T1<T2. By precisely controlling the temperature gradient, vapor pressure, and the amount of intercalants, intercalation compounds of graphene with different qualities can be obtained. In general, preparation conditions may vary depending on the type of intercalant.

In another exemplary application, GSG nanosheets having surface functionalized molecules deposited on its external surfaces may be used for biological or chemical sensing applications.

It is to be understood that the foregoing description is intended to illustrate and not to limit the scope of the invention, which is defined by the scope of the appended claims. Other embodiments are within the scope of the following claims.

What is claimed is:

1. A nanosheet comprising:
a 2H—SiC layer having a first surface and a second surface, the first and second surfaces being opposed to each other;
a first graphene layer formed of 1-10 graphenes being disposed on the first surface; and
a second graphene layer formed of 1-10 graphenes being disposed on the second surface.

2. The nanosheet of claim 1, wherein the 2H—SiC layer has a thickness of 3-15 nm.

3. The nanosheet of claim 1, wherein the 2H—SiC layer has a thickness of 3-7 nm.

4. The nanosheet of claim 1, wherein at least one of the first surface and the second surface is a 2H—SiC {0001} crystal plane.

5. The nanosheet of claim 1, wherein the nanosheet is disposed on a surface of a substrate, the first and second surfaces of the 2H—SiC layer being substantially perpendicular to the substrate surface.

6. The nanosheet of claim 5, wherein the substrate is silicon; germanium; a ceramic material; a carbonaceous material; a metal selected from the group consisting of Ni, Co, Fe, W, Mo, and stainless steel; or a combination thereof.

7. The nanosheet of claim 5, wherein the substrate is silicon or germanium and the surface of the substrate is a {100}, {110}, or {111} crystal plane.

8. The nanosheet of claim 1, further comprising a plurality of nanoparticles disposed on the first or second graphene layer.

9. The nanosheet of claim 8, wherein the plurality of nanoparticles each is formed of a metal, a metal oxide, a metal nitride, or combination thereof.

10. The nanosheet of claim 1, further comprising a plurality of ions intercalated in the first or second graphene layer, the ions being selected from the group consisting of Li, Na, Be, Mg, and Ca.

11. The nanosheet of claim 1, wherein at least one of the first graphene layer and the second graphene layer is tensilely strained.

12. The nanosheet of claim 1, wherein at least one of the first graphene layer and the second graphene layer is compressively strained.

13. An article comprising:
a substrate having a surface; and
a plurality of nanosheets disposed on the surface of the substrate, each nanosheet comprising:
a SiC layer having a first surface and a second surface, the first and second surfaces opposed to each other and substantially perpendicular to the surface of the substrate,
a first graphene layer formed of 1-10 graphenes being disposed on the first surface, and
a second graphene layer formed of 1-10 graphenes being disposed on the second surface,
wherein the density of nanosheets per unit area is at least 10⁹ cm⁻².

14. The article of claim 13, wherein the density of nanosheets per unit area is in the range of 10⁹ to 10¹² cm⁻².

15. The article of claim 13, wherein the SiC layer is formed of 2H—SiC.

16. A method of making the article of claim 13, the method comprising:
placing a substrate in a chemical vapor reactor that contains a gas mixture; and
heating the substrate at a temperature in the range of about 900-1250° C. such that a plurality of nanosheets are formed on a surface of the substrate,
wherein the gas mixture comprises an inert gas, a silicon-containing gas, a carbon-containing gas, and hydrogen gas.

17. The method of claim 16, wherein the silicon-containing gas is silane.

18. The method of claim 16, wherein the carbon-containing gas is methane.

19. The method of claim 16, wherein a pressure in the chemical vapor reactor is in the range of 40-80 Torr.

20. The method of claim 16, wherein the chemical vapor reactor is at least one of a microwave plasma reactor, a radio frequency plasma reactor, an induction coupled plasma reactor, a direct current plasma reactor, or a hot filament reactor.
